(19) United States
(12) Patent Application Publication
(10) Pub. No.: US 2006/0125076 A1
(43) Pub. Date: Jun. 15, 2006

(54) Circuit boards, electronic devices, and methods of manufacturing thereof

(75) Inventors: Masato Fukagaya, Nagoya (JP); Osamu Koido, Nagoya (JP)

Correspondence Address: LAHIVE & COCKFIELD, 28 STATE STREET, BOSTON, MA, 02109, US

(73) Assignee: SOHKi Co., Ltd., Nagoya (JP)

(21) Appl. No.: 11/096,452

(22) Filed: Mar. 31, 2005

(30) Foreign Application Priority Data
Mar. 31, 2004 (JP) 2004-102194

(51) Int. Cl. H01L 23/48

(52) U.S. Cl. 257/690

(57) ABSTRACT

A circuit board 3 includes a ceramic substrate 6 with an internal layer circuit 7 therein. The internal layer circuit 7 is used to electroplate a plurality of component electrodes 8, a plurality of terminal electrodes 9, and a loop electrode 10 that surrounds the component electrodes 8 on surfaces of the substrate 6 by using the internal layer circuit 7. A hole is bored in a periphery of the substrate 6 to sever the internal layer circuit 7 and isolate the component electrodes 8 from the loop electrode 10. Part of the severed internal layer circuit 7 is then used to electroplate a surface of the loop electrode 10 with a brazing material 5 to provide the circuit board 3.

### RELATED APPLICATION

This application claims priority on Japanese Patent Application No. 2004-102194 filed on Mar. 31, 2004.

### BACKGROUND OF THE INVENTION

1. Field of the Invention

The present invention relates to circuit boards on which electronic components are mounted on, methods of fabricating such circuit boards, electronic devices incorporating such circuit boards, and methods of fabricating such electronic devices.

2. Description of the Related Art

A known package for an electric device comprises a circuit board on which electronic components are mounted, a cover or lid fitted over the electronic components, and a brazing material that bonds or joins the cover and the circuit board together. For example, Japan Published Unexamined Patent Application No.2003-158211 discloses a package for an electronic device comprising a circuit board and a cover bonded to the circuit board by seam-welding. To assemble the package, a brazing material is first cladded on the cover by rolling and then melted by seam welding to bond the cover to the circuit board.

Japan Published Unexamined Patent Application No. 2003-133465 discloses a circuit board in which a brazing material is applied onto the top surfaces of the side walls of a recessed ceramic substrate. Another known circuit board includes a brazing material applied onto a surface of the substrate by screen printing. In still another packaging technology, a seal ring or alloy foil with a low melting point is interposed between the circuit board and the cover.

According to the packaging of Japan Published Unexamined Patent Application No. 2003-158211, however, since the brazing material is disposed on the cover, the brazing material tends to be out of alignment with the circuit board if the board is deformed by the heat of seam welding. This often adversely affects the air-tightness of the package and/or lowers the bonding strength of the brazing material.

The packaging of a circuit board according to Japan Published Unexamined Patent Application No. 2003-133465 provides the advantage of limiting the adverse effect of the heat shrinkage or other deformation of the substrate since the brazing material is disposed on the substrate. However, in order to apply the brazing material with a degree of high precision, this technology requires dividing a substrate in advance into smaller, individual substrates each matching the size of the electronic device to be fabricated. This requirement to use smaller divided substrates disadvantageously lowers the productivity of the packaging process.

In a circuit board in which a brazing material is applied by printing, when the ceramic substrate shrinks or otherwise deforms due to the heat of the firing, the print pattern may not be accurately disposed on the specified position. Such substrate shrinkage makes it particularly difficult to perform printing on micro circuit boards with a required degree of precision. According to the technology that employs a seal ring or alloy foil as a brazing material, the brazing material need be disposed on individual circuit boards one by one and thus lowers the manufacturing productivity. In addition, the brazing material increases the thickness of the package, making it difficult to provide a thin electronic device.

### SUMMARY OF THE INVENTION

In view of the above-identified problems, an important object of the present invention is to provide a circuit board in which a brazing material is integrated with a substrate with a high degree of precision.

Another object of the present invention is to provide a method of manufacturing this circuit board easily with a high degree of and precision.

Still another object of the present invention is to provide a thin, air-tight electronic device that utilizes the circuit board.

Yet another object of the present invention is to provide a method of efficiently manufacturing a large number of electronic devices with a high degree of precision.

The above objects and other related objects are realized by the invention, which provides a circuit board comprising:

a substrate that includes an insulating material;

at least one component electrode and at least one loop electrode that surrounds the component electrode both electroplated on the substrate using the same metallic material; and

a brazing material electroplated on the loop electrode.

There is no particular limitation for the type or the application of the circuit board, such that various electronic devices may be fabricated depending on the electronic components included or mounted on the circuit board. Furthermore, one electronic device may be implemented on one circuit board. Alternatively, a plurality of electronic devices is manufactured from a single circuit board. When manufacturing micro electronic devices, it is preferable to employ a collective circuit board. More particularly, a plurality of board regions may be defined on a surface of the substrate, at least one component electrode and at least one loop electrode may be electroplated within each board region, and a brazing material is electroplated on the loop electrode within each board region.

There is no particular limitation for the material for the substrate; for example, the materials suitable for the substrate include high-temperature cofired ceramic (HTCC), low-temperature cofired ceramic (LTCC), liquid crystal polymer (LCP), Teflon®, fluororesin, glass epoxy, and other insulating materials. Preferably, the substrate has a double sided structure or a multilayer structure containing an internal layer circuit since such a circuit can be utilized to electroplate the substrate with the electrodes and the brazing material.

The substrate may be of a cavity-type, a flat-type, or one with an H-shaped cross section. However, cavity-type ceramic substrates with a recess and ceramic substrates with an H-shaped cross section are prone to develop warpage in the side walls due to the heat of the firing. In addition, substrates with an H-shaped cross section generally have the drawback of increased thicknesses of the resultant circuit boards. Conversely, substrates with a flat surface are less susceptible to heat deformation during the forming, thus advantageously providing thinner circuit boards.

There is no particular limitation for the number or the shape of the component electrodes mounted on the substrate; any suitable number and/or the shape of the component electrodes may be employed, depending on the type and/or number of electronic components to be included on the board. The loop electrode serves as the support and the plating electrode for the brazing material. The loop electrode may be formed, for example, in a circle, triangle, rectangle, polygon, or any other suitable shape; however, a preferred shape is rectangular. The component and loop electrodes (the metallized portions) are formed by electroplating or electroless plating using the same metallic material. No particular limitation exists for the material for this plating; for example, gold (Au), silver (Ag), copper (Cu), Nickel (Ni), palladium (Pd), gold-tin alloy (Au—Sn), or silver-tin alloy (Ag—Sn) may be used for this purpose.

It is advantageous to use internal layer circuitry laid or otherwise included in the substrate as the circuitry for plating the component and loop electrodes A single internal layer circuit may be designed in a pattern that has continuity with both the component electrode(s) and the loop electrode(s). Alternatively, separate internal layer circuits may be designed in separate patterns each having continuity with either the component electrode(s) or the loop electrode(s). In the former case, the single pattern is used to form both the component electrode and the loop electrode simultaneously. The loop electrode is then isolated from the component electrode so that the part of the pattern having continuity with the loop electrode only is used to electroplate the brazing material on the loop electrode. In the later case, the separate patterns are used to form the component electrode and the loop electrode. The pattern in electrical continuity with the loop electrode only is used to electroplate the brazing material on the loop electrode.

The brazing material serves as the sealer or material for bonding the cover of the electronic device or the package to the circuit board in an air-tight manner and is secured on a surface of the loop electrode by electroplating or electroless plating. The material for plating may be selected so as to ensure the brazing material is securely bonded to the loop electrode and the cover. For example, gold (Au), silver (Ag), copper (Cu), Nickel (Ni), tin (Sn), gold-tin alloy (Au—Sn), silver-tin alloy (Ag—Sn), tin-zinc alloy (Sn—Zn), or any suitable solder may be used for this purpose. A relatively thick plate of gold-tin alloy or gold is preferred due to their superior ability to bond to the metal cover (i.e., wettability).

In particular, gold-tin alloy has a higher melting point than solder, such that the heat generated during device mounting will not melt this alloy. Additionally, the use of this relatively inexpensive alloy provides a highly air-tight package at a relatively low cost. Accordingly, a preferred combination of the plating materials is gold for the component electrode and the loop electrode and gold-tin alloy for the brazing material. Moreover, to prevent the brazing material from oxidation, this material may be electroplated with an antioxidant layer (for example, gold or nickel).

In addition, the present invention offers a method of manufacturing the above-described circuit board in a simple manner. This method comprises the steps of:

providing a substrate which contains an insulating material and includes at least one internal layer circuit;

simultaneously electroplating at least one component electrode and at least one loop electrode that surrounds the component electrode on the substrate, the component electrode and the loop electrode being electroplated from the same metallic material by using the internal layer circuit;

severing the internal layer circuit to isolate the component electrode from the loop electrode, and

electroplating a brazing material on the loop electrode by using part of the severed internal layer circuit.

The present invention additionally provides a method of manufacturing a collective circuit board suitable for obtaining a multiplicity of micro devices therefrom. This method comprises the steps of:

defining a plurality of board regions on a surface of the substrate;

electroplating at least one component electrode and at least one loop electrode within each board region;

making at least one hole outside of the board regions in an outer edge of the substrate to sever at least one internal layer circuit included in the substrate; and

electroplating a brazing material on the loop electrode within each board region by using the part of the at least one internal layer circuit that does not include the hole.

According to this manufacturing method, as the at least one internal layer circuit is severed in the outer edge of the substrate, relatively simple means of making holes, such as laser or drilling, can be utilized for this purpose. The severing simultaneously isolates all the loop electrodes from the component electrodes so as to facilitate the two-stage electroplating in an efficient manner. The materials for electroplating the electrodes and the brazing material can be selected from the various metallic materials listed above. Preferably, a different metallic material is selected for plating the brazing material than that for the component and loop electrodes. In this way, the two-stage electroplating of this method permits manufacture of a wide variety of circuit boards by selecting the materials for the electrodes and the brazing material to suit the function and/or the assembly conditions (such as the temperature of the atmosphere in which the brazing material is melted) of the circuit board or the type of the electronic device to be fabricated.

The present invention additionally provides an electronic device that employs any of the foregoing circuit boards; at least one electronic component mounted on the at least one component electrode; and a cover bonded to the substrate via the brazing material so as to cover the electronic component.

It should be noted that there is no particular limitation for the type and/or the number of electronic components to be mounted on the board. For example, one or more of various electronic components or any combination thereof may be selected from piezoelectric vibrators, elastic surface-wave devices, optics, IC chips, transistors, resistors, capacitors, diodes, and any other suitable elements and components, according to the intended use of the electronic device. Flat covers may be used with cavity-type substrates or with substrates having an H-shaped cross section. Hat-shaped covers with a surrounding flange or covers with a flat top and a recess at the bottom (e.g., generally in an inverted cup-shape) may be used in combination with flat substrates. Although ceramics or resins can be used as the materials for these covers, metal is preferred for its excellent heat dissipation characteristics and its ability to form a smooth and flat interface with the brazing material for improved bonding therebetween. In one embodiment, the metal cover includes on its periphery (the flange) a metal layer that bonds well to the brazing material.

The present invention additionally provides a method suitable for obtaining a multiplicity of micro electronic devices. This method comprises the steps of: providing a collective circuit board manufactured by the above-described method; mounting at least one electronic component on the at least one component electrode within each board region; positioning at least one cover on the substrate so as to cover the electronic components; bonding the cover to the substrate by melting the brazing material on each board region; and cutting the substrate along the boundaries that define the board regions.

In this method, the same number of separate covers as that of the board regions may be used. Preferably, however, a single, common cover for all the regions is used to manufacture electronic devices more efficiency. In one embodiment, after a single cover is bonded to the substrate to cover the electronic components within the board regions, the substrate and the cover are cut or severed along the boundaries defining the board regions.

The circuit boards manufactured according to the present invention provides the advantage that the positioning of the brazing material is not affected by shrinkage or other deformation of the substrate and can be integrated with the substrate with a high degree of precision since both the loop electrode and the brazing material are electroplated on the substrate.

The methods of manufacturing a circuit board according to the present invention advantageously manufacture a circuit board that integrates a brazing material in a simple and precise manner since the component and loop electrodes as well as the brazing material are formed by electroplating with the internal layer circuitry of the substrate.

As described above, the electronic devices of the present invention include a brazing material integrated with the circuit board. Upon assembly, the brazing material is thinly and uniformly interposed between the substrate and the cover, advantageously providing thin devices with high air-tightness.

The methods of manufacturing electronic devices according to the present invention permit efficient manufacture of a large number of devices with a high degree of precision as this method employs a collective circuit board with an integrated brazing material.

### BRIEF DESCRIPTION OF THE ATTACHED DRAWINGS

For a fuller understanding of the nature and objects of the present invention, reference should be made to the following detailed description and the accompanying drawings, in which:

FIG. 1 is a perspective view of an electronic device according to one embodiment of the present invention, showing its cover detached from its substrate;

FIG. 2 shows a cross section of the electronic device in FIG. 1;

FIG. 3 is a perspective view of a collective circuit board according to the present invention;

FIGS. 4A-E show an exemplary process of manufacturing the circuit board shown in FIG. 1;

FIGS. 5A-C show another exemplary process of manufacturing the electronic device shown in FIG. 1;

FIG. 6 shows an alternate embodiment of a circuit board according to the present invention; and

FIG. 7 shows another alternate embodiment of a circuit board according to the present invention.

### DETAILED DESCRIPTION OF THE PREFERRED EMBODIMENTS

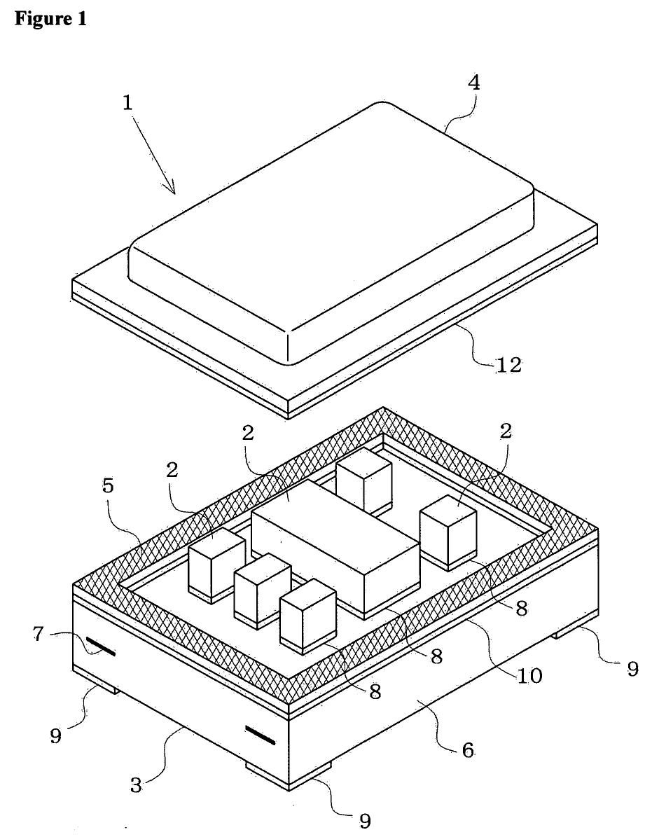

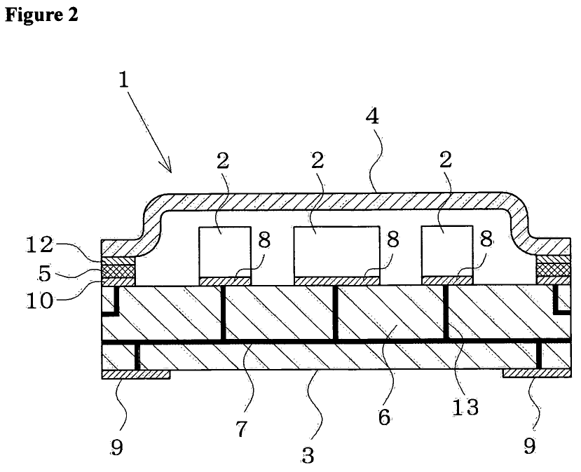

Preferred embodiments of the present invention will be described hereinafter with reference to the attached drawings. FIGS. 1 and 2 show an electronic device 1 of an exemplary embodiment that includes a circuit board 3 on which a plurality of electronic components 2 are mounted and a cover or lid 4 disposed over the electronic components 2. A brazing material 5 is disposed integrally on the top peripheral surface of the circuit board 3, whereas a metal layer 12 is disposed on the bottom peripheral surface of the cover 4. The cover 4 is air-tightly bonded to the circuit board 3 by thermo-compression bonding of the brazing material 5 and the metal layer 12.

Referring to FIG. 2, for example, the substrate 6 of the circuit board 3 is formed from a high-temperature or low-temperature cofired ceramic material to have a plurality of layers. The substrate 6 includes flat surfaces and contains an internal layer circuit 7 that has continuity with the electronic components 2 of the device 1. Arranged on surfaces of the substrate 6 are a plurality of component electrodes 8 on which the electronic components 2 are mounted, a plurality of terminal electrodes 9 for connection with an equipment board, such as a mother board (not shown), and a loop electrode 10 that surrounds the component electrodes 8. In this embodiment, six component electrodes and one loop electrode are showed to be formed on the substrate 6; however, those with ordinary skill in the art will appreciate that the number of these electrodes may be altered according to the application of the electronic device without departing from the scope of the invention.

The electrodes 8, 9, and 10 are metallized portions of the circuit board 3 and all made of the same metallic material. These metallized electrodes are simultaneously formed by electroplating using the internal layer circuit 7 inside the substrate 6. The brazing material 5 is electroplated on the loop electrode 10 by using part of the internal layer circuit 7. The cover 4 is thermo-compression bonded to the substrate 6 by the brazing material 5. In this embodiment, gold is used to plate the electrodes 8, 9, and 10 on the substrate 6, whereas gold-tin alloy is used to plate the brazing material 5 on the electrode 10 due to its relative inexpensiveness and its ability to bond well to gold. The metal layer 12 of the cover 4 includes a base layer of nickel and a surface layer of gold, which bonds well to or joins well with the brazing material 5. These layers are disposed on the cover 4 by electroplating or rolling.

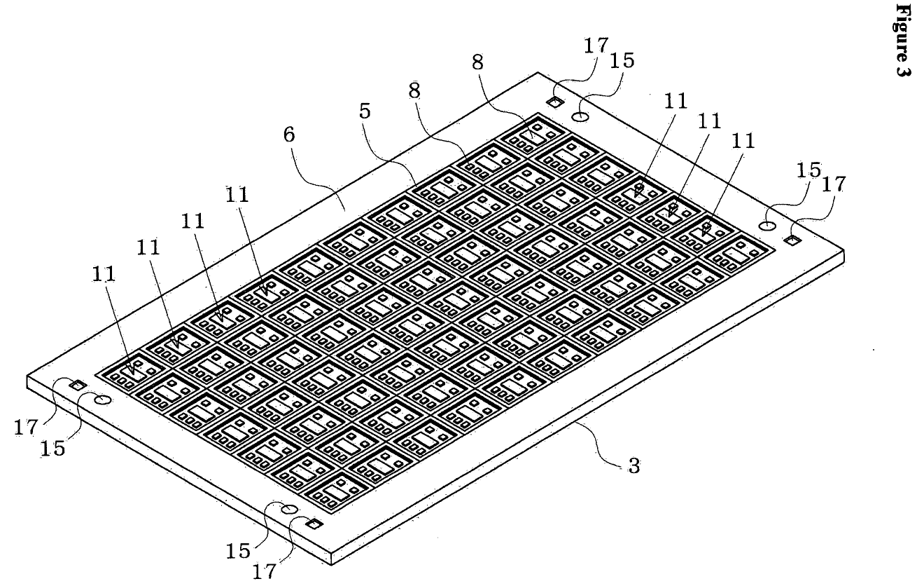

A single circuit board 3 may be provided in the form of a single board or a collective board. In the latter case, as shown in FIG. 3, for example, a large number of board regions 11 are defined on the surface of a substrate 6. Electroplated within each of the board regions 11 are component electrodes 8, terminal electrodes 9, and a loop electrode 10. A brazing material 5 is disposed on each loop electrode 10 by electroplating as well. For example, 3,000 individual circuit boards, each having a length of 1.0 mm and a width of 1.5 mm, may be obtained from a square collective board with sides of 110 mm and a thickness of 0.2 mm.

According to a circuit board 3 as constructed as above, since the loop electrode 10 and the brazing material 5 are both electroplated on the substrate 6, the positioning of the brazing material 5 is not adversely affected by the heat deformation of the substrate 6 and the brazing material 5 can be integrated with the substrate 6 with a high degree of precision. Particularly, if a collective substrate 6 is used, a large number of circuit boards 3 can be manufactured and obtained with high precision and in an efficient manner. The electronic device 1 of the embodiment offers a number of advantages. First, the brazing material 5, as it is evenly and thinly interposed between the substrate 6 and the cover 4 by electroplating, allows the entire device 1 to be significantly thin and highly air-tight. In particular, when a collective board, such as the circuit board 3 shown in FIG. 3, is used, a large number of thin or low-profile and airtight electronic devices 1 can be obtained from the single circuit board 3 in an efficient manner.

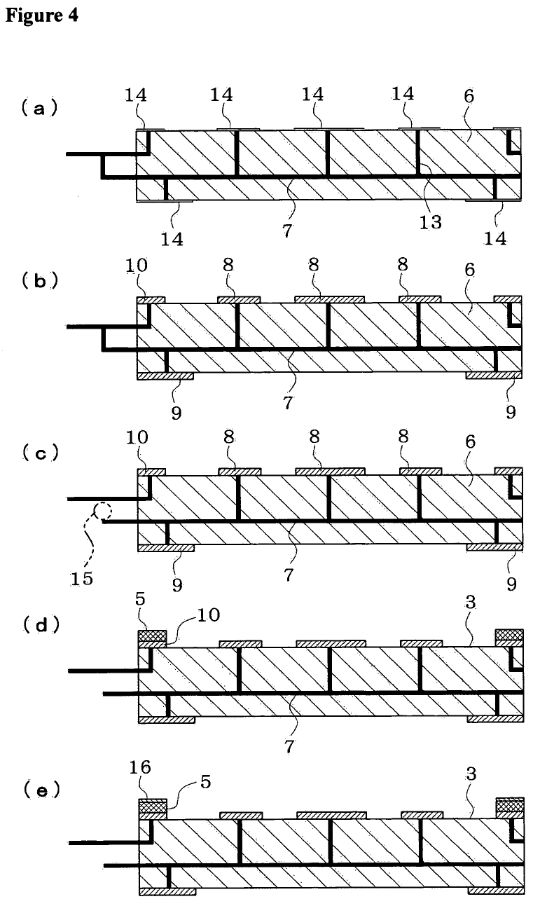

The following describes preferred methods of manufacturing the single and collective circuit boards 3 and the electronic device 1 according to the present invention. It should be noted that either a single or collective circuit board 3 may be manufactured by the method illustrated in FIG. 4. As shown in FIG. 4A, a required number of green sheets are laminated with an internal layer circuit 7 having via holes 13 disposed therein to provide a multilayer ceramic substrate 6. Next, an electrode pattern 14 is formed on the locations for the electrodes on the substrate 6 by screen printing conductive paste which contains tungsten, nickel, and/or silver alloy. Then, the substrate 6, now with the electrode pattern 14, is fired.

In the plating step shown in FIG. 4B, the internal layer circuit 7 is used as the plating circuit, with terminal holes 17 (see FIG. 3) of the circuit 7 connected to the plating power source (not shown) so as to simultaneously electroplate the electrode pattern 14 with component electrodes 8 and terminal electrodes 9, and a loop electrode 10 using the same metallic material. An exemplary method of forming these electrodes includes electroplating or electroless-plating these locations 14 with a nickel base layer having a thickness of 2-6 micrometers and additionally plating a gold layer having a thickness of 0.5-5 micrometers. Next, as shown in FIG. 4C, a hole 15 is made in the periphery of the substrate 6 by laser or drilling so as to sever the internal layer circuit 7 and thus isolate or separate the component electrodes 8 and the terminal electrodes 9 from the loop electrode 10.

As shown in FIG. 4D, a brazing material 5 is electroplated on the loop electrode 10 using part of the severed internal layer circuit 7 (i.e., the part of the circuit pattern that has continuity only with the loop electrode 10). The preferred material for plating the brazing metal 5 on the electrode 10 is gold-tin alloy having a melting point of about 278 degrees Celsius. The alloy may contain 75-85% gold and 25-15% tin. The preferred ratio of gold to tin is 8 to 2 (i.e., 80% gold and 20% tin in the alloy). Preferably, the brazing material 5 has a thickness of about 3-35 micrometers (μm). Subsequently, as shown in FIG. 4E, if required, the brazing material 5 is electroplated with an antioxidant layer 16 of gold to complete the manufacture of the circuit board 3.

As a next step, as shown in FIG. 2, after the electronic components 2 are mounted on the respective component electrodes 8 on the substrate 6, the cover 4 is set in place over the electronic components 2 on the substrate 6. A predetermined load is then applied to the cover 6 in an atmosphere of about 300 degrees Celsius to melt the brazing material 5 such that the melted brazing material 5 is thermo-compression bonded to the metallic layer 12 of the cover 4, thus securing the cover 4 on the substrate 6. Subsequently, a process of inspection including air-tightness testing and circuit testing is performed on the product to complete the manufacture of the electronic device 1.

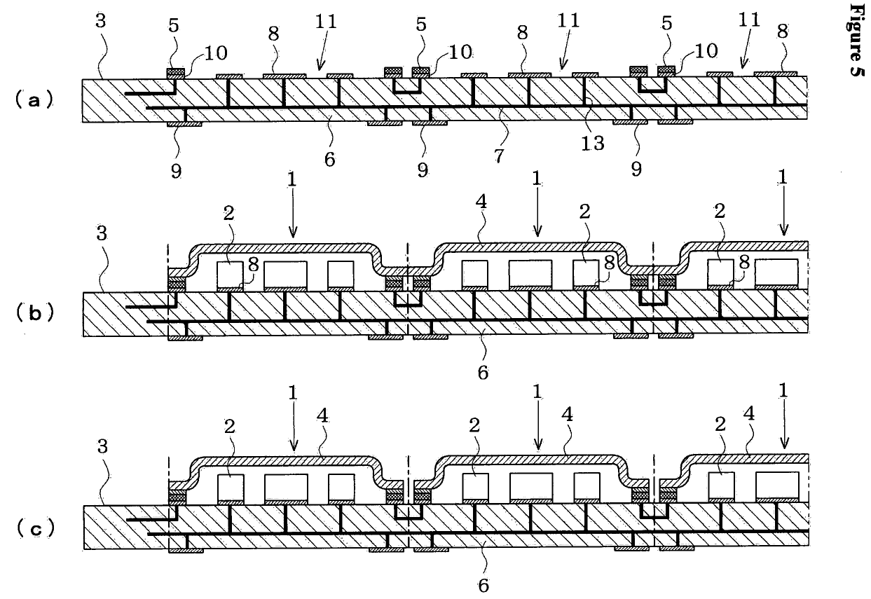

In the case of a collective board, as shown in FIG. 5A, a plurality of board regions 11 are defined on the substrate 6. After component electrodes 8, terminal electrodes 9, and a loop electrode 10 are formed within each board region 11, holes 15 (see FIG. 3) are machined outside of the board regions 11 in the outer edges in order to sever the internal layer circuits 7. A brazing material 5 is disposed on the loop electrode 10 within each board region 11 using the parts of the severed internal layer circuits 7 that include no holes 15 (i.e., the part of the circuit pattern that has continuity only with the loop electrodes 10 of the board regions 11). In the embodiment of FIG. 3, four holes are machined in the outer edges or margins of the substrate 6. It should be noted, however, that the number of these holes is a matter of design choice and that any number (fewer or more than in the illustrated embodiment) of holes 15 may be provided to suit particular applications. For example, only one hole 15 may be required depending on the design of the internal layer circuit pattern.

As a next step, as shown in FIG. 5B, electronic components 2 are mounted on the component electrodes 8 within each board region 11, and then a single cover 4 is positioned on the substrate 6 so as to cover the electronic components 2 within all of the board regions 11. With the cover 4 properly positioned over all the board regions 11 and their respective components 2, the brazing material 5 is melted on the board regions 11 to bond the cover 4 to the substrate 6. As a next step, the substrate 6 is cut into multiple pieces along the boundaries defining the board regions 11 (indicated in the dot and dash lines in the figure) by laser or dicing, thus permitting a large number of electronic devices 1 to be obtained from the single circuit board 3. As shown in FIG. 5C, as an alternative method to manufacture a plurality of electronic devices 1 from a single substrate, the same number of separate covers 4 as that of the board regions 11 may be first bonded to the substrate 6 for subsequent dicing of the substrate 6 only.

According to the method of manufacturing the circuit board 3 of this embodiment, the component electrodes 8, the terminal electrodes 9, the loop electrode 10, and the brazing material 5 are all electroplated by using the internal layer circuitry 7, permitting integration of the brazing material 5 with the circuit board 3 with high precision in a simple process. In particular, when a collective board is used, a large number of circuit boards 3 can be manufactured from a single substrate 6 with high precision and in an efficient manner. Furthermore, the method of this embodiment for manufacturing the electronic devices 1 employs a collective board with an integrated brazing material so as to advantageously permit the manufacture of a large number of devices 1 from the single circuit board 3 with great efficiency and high precision.

One of ordinary skill in the art will additionally appreciate that the above embodiments are only an illustration and not restrictive in any sense and that there are different ways to alter the parameters of the embodiments disclosed, such as the size, shape, or type of elements or materials, in a manner still in keeping with the spirit and scope of the present invention as shown below.

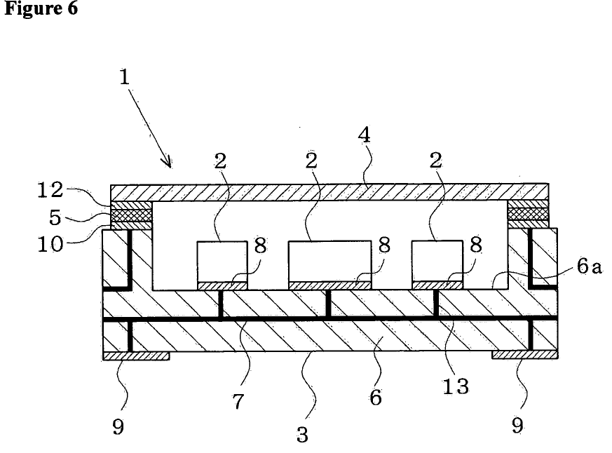

For example, in an alternative embodiment, as shown FIG. 6, a cavity-type substrate 6 with a recess 6a is used to accommodate electronic components 2 in the recess 6a, with a flat cover 4 bonded to a surface of the substrate 6 via a brazing material 5 in order to roof or cover the electronic components 2.

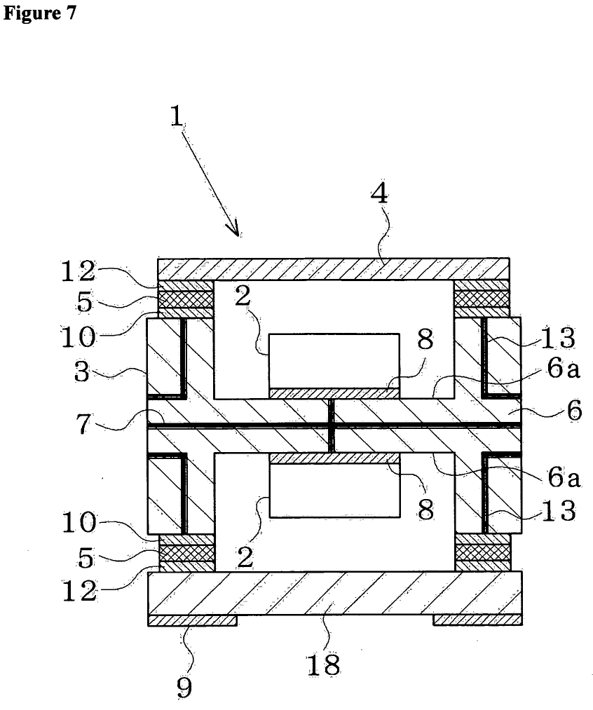

In another alternative embodiment, as shown in FIG. 7, a substrate 6 with an H-shaped cross section is used to accommodate two electronic components 2 in upper and lower recesses 6a. In this structure, a cover 4 is bonded to the upper surface of the substrate 6 via a brazing material 5 in order to roof the upper electronic component 2, whereas an insulating plate 18 is bonded to the lower surface of the substrate 6 via a brazing material 5 in order to cover the lower electronic component 2.

Having described the invention, what is claimed as new and desired to be secured by Letters Patent is:

1. A circuit board comprising:
a substrate that includes an insulating material;
at least one component electrode and at least one loop electrode that surrounds the component electrode, wherein both of said component electrode and said loop electrode are electroplated on the substrate using the same metallic material; and
a brazing material electroplated on the loop electrode.

2. A circuit board in accordance with claim 1, wherein a plurality of board regions is defined on the substrate, at least one component electrode and at least one loop electrode is electroplated within each board region on the substrate, and a brazing material is electroplated on the loop electrode within each board region.

3. A circuit board in accordance with claim 1, wherein gold is used for plating the component and loop electrodes and gold-tin alloy is used for plating the brazing material.

4. A circuit board in accordance with claim 2, wherein gold is used for plating the component and loop electrodes and gold-tin alloy is used for plating the brazing material.

5. A circuit board in accordance with claim 1, wherein the substrate has substantially flat surfaces.

6. A circuit board in accordance with claim 2, wherein the substrate has substantially flat surfaces.

7. A circuit board in accordance with claim 3, wherein the substrate has substantially flat surfaces.

8. A circuit board in accordance with claim 4, wherein the substrate has substantially flat surfaces.

9. A method of manufacturing a circuit board, comprising the steps of:
providing a substrate which contains an insulating material and includes at least one internal layer circuit;
simultaneously electroplating at least one component electrode and at least one loop electrode that surrounds the component electrode on the substrate, the component electrode and the loop electrode being electroplated from the same metallic material by using the at least one internal layer circuit;
severing the at least one internal layer circuit to isolate the component electrode from the loop electrode, and
electroplating a brazing material on the loop electrode by using part of the severed internal layer circuit.

10. A method in accordance with claim 9 further comprising the step of defining a plurality of board regions on the substrate,
wherein the step of simultaneously electroplating includes electroplating at least one component electrode and at least one loop electrode within each board region;
the step of severing the at least one internal layer circuit includes making at least one hole outside of the board regions in an outer edge of the substrate to sever the at least one internal layer circuit in the substrate; and
the step of electroplating a brazing material includes electroplating the brazing material on the loop electrode within each board region by using the part of the at least one internal layer circuit that does not include the hole.

11. A method in accordance with claim 9, wherein the metallic material used to plate the brazing material is different from the metallic material used to plate the component and loop electrodes.

12. A method in accordance with claim 10, wherein the metallic material used to plate the brazing material is different from the metallic material used to plate the component and loop electrodes.

13. An electronic device comprising a circuit board of claim 1, an electronic component mounted on each of the at least one component electrode, and a cover bonded to the substrate via the brazing material so as to cover the electronic component.

14. A method of manufacturing electronic devices, comprising the steps of:
providing a circuit board manufactured by the method of claim 10; mounting an electronic component on the at least one component electrode within each board region; positioning at least one cover on the substrate so as to cover the electronic components; bonding the cover to the substrate by melting the brazing material on each board region; and cutting the substrate along the boundaries that define the board regions.

15. A method in accordance with claim 14, wherein after a single cover is bonded to the substrate to cover the electronic components within the board regions, the substrate and the cover are cut along the boundaries defining the board regions.
